(19) United States
(12) Patent Application Publication
(10) Pub. No.: US 2014/0255678 A1
(43) Pub. Date: Sep. 11, 2014

(54) METHOD OF FABRICATING POLYENE CONTAINING POLARIZING FILM, POLYENE CONTAINING POLARIZING FILM FABRICATED USING THE SAME, POLARIZING PLATE INCLUDING THE SAME, AND DISPLAY INCLUDING THE SAME

(71) Applicant: Chell Industries Inc., Gumi-si (KR)

(72) Inventors: Shigeto Kobori, Yokohamashi (JP); Takashi Takagi, Yokohamashi (JP); Atsushi Sato, Yokohamashi (JP)

(73) Assignee: Cheil Industries Inc., Gumi-si (KR)

(21) Appl. No.: 14/144,385

(22) Filed: Dec. 30, 2013

(30) Foreign Application Priority Data
Dec. 28, 2012 (JP) 2012-287727
Sep. 25, 2013 (KR) 10-2013-0114116

(51) Int. Cl. H01L 51/52; G02B 1/04; H01L 51/56; G02B 1/08

(52) U.S. Cl. CPC H01L 51/5293; G02B 1/08; G02B 1/04; H01L 51/56
USPC 428/220; 524/557; 427/163.1; 264/1.34

(57) ABSTRACT

A method of fabricating a polarizing film having excellent optical properties. The method includes fabricating a polyvinyl alcohol film using a coating liquid including an acid catalyst and a polyvinyl alcohol, and dehydrating the polyvinyl alcohol film. In this method, a high concentration of the acid catalyst is uniformly dispersed in the polyvinyl alcohol film.

### CROSS-REFERENCE TO RELATED APPLICATIONS

This application claims priority to and the benefit of Japanese Patent Application No. 2012-287727, filed in the Japanese Patent Office on Dec. 28, 2012, and Korean Patent Application No. 10-2013-0114116, filed in the Korean Intellectual Property Office on Sep. 25, 2013, the entire contents of both are incorporated herein by reference.

### BACKGROUND

1. Field

The following description relates to a method of fabricating a polyene containing polarizing film, a polyene containing polarizing film, a polarizing plate, and a display.

2. Description of the Related Art

In organic light emitting displays using organic light emitting diodes (OLED), a polarizing film is required to have improved transmittance. Iodine based polarizing films are known and broadly used as polarizing films for various displays.

In the iodine based polarizing film, a main component for the polarization function (namely, the component that absorbs visible light) is iodine. Thus, it is necessary to decrease the amount of iodine in the polarizing film in order to increase the transmittance of the polarizing film. However, since iodine may be sublimated under high temperature and high humidity conditions, the polarizing film may suffer from a lack of iodine if the amount of iodine in the polarizing film is decreased, thereby causing significant reduction in the degree of polarization of the polarizing film. As a result, the iodine based polarizing film having high transmittance (for example, transmittance of 44% or more) suffers from a reduction in long term reliability under high temperature and high humidity conditions.

To resolve such a problem, a dye-based polarizing film and a polyene containing polarizing film disclosed in JP2006-99076 A are known in the art. The dye-based polarizing film may exhibit excellent heat resistance even when the dye-based polarizing film has high transmittance. However, the dye-based polarizing film has a drawback in that the degree of polarization is likely to decrease when the dye-based polarizing film has high transmittance.

Although the polyene containing polarizing film has a slightly lower degree of polarization than the iodine based polarizing film, the polyene containing polarizing film has an advantage in that, even when the polyene containing polarizing film exhibits high transmittance, the polyene containing polarizing film still has high reliability under high temperature and high humidity conditions. This is because the main component for polarization (namely, the component that absorbs visible light) in the polyene containing polarizing film is polyene (specifically, the carbon-carbon double bonds). The carbon-carbon double bonds are not affected by temperature or humidity. Thus, the polyene containing polarizing film exhibits (basically exhibits) high durability under high temperature and high humidity conditions. For this reason, the polyene containing polarizing film has attracted considerable attention as a polarizing film for displays.

As a method of fabricating a polyene containing polarizing film, a process of dehydrating polyvinyl alcohol (PVA) using an acid catalyst is known in the art. Specifically, a polyvinyl alcohol film is impregnated in an aqueous solution of an acid catalyst, followed by heat treatment of the polyvinyl alcohol film to dehydrate polyvinyl alcohol, thereby fabricating a polyene containing polarizing film. As the acid catalyst, hydrochloric acid or sulfuric acid is used.

However, when hydrochloric acid is used as the acid catalyst, the acid catalyst is evaporated as hydrogen chloride gas together with the evaporation of water upon heat treatment of the polyvinyl alcohol film. As a result, it becomes very difficult to control the acid concentration in the polyvinyl alcohol film. When there is deviation in the acid concentration of polyvinyl alcohol, the polyene containing polarizing film is likely to suffer from deviation or non-uniformity in the optical properties, such as transmittance, degree of polarization, or the like.

In order to solve these problems, it is contemplated that the acid concentration in the polyvinyl alcohol film may be made uniform by controlling temperature, humidity and atmosphere during heat treatment. However, this method requires a complicated structure of a fabrication apparatus.

On the other hand, sulfuric acid is not easily evaporated (volatilized). However, since sulfuric acid had an excessively strong dehydration function, sulfuric acid may provide undesirable effects, such as dehydration between molecules upon heat treatment or PVA backbone breakage, and may easily deteriorate the optical properties of the polyene containing polarizing film, when used as the acid catalyst.

As such, a typical method of fabricating a polyene containing polarizing film does not satisfy the requirement of production stability and optical performance. Japanese Patent Publication No. 2006-099076A discloses the use of an organic acid as the acid catalyst. However, even in this case, it is difficult to obtain constant acid concentration in polyvinyl alcohol.

Therefore, one or more embodiments of the present invention are directed toward a method of fabricating an improved polarizing film capable of stably preparing a polarizing film having excellent optical properties.

### SUMMARY

According to an embodiment of the present invention, a method of fabricating a polyene containing polarizing film includes: fabricating a polyvinyl alcohol film using a coating liquid including an acid catalyst and polyvinyl alcohol, and dehydrating the polyvinyl alcohol film. According to this embodiment, since it is possible to uniformly disperse the acid catalyst at high concentration in the polyvinyl alcohol film, a polyene containing polarizing film having multiple carbon-carbon double bonds uniformly formed therein may be fabricated without the need of accurate control of the environmental conditions such as temperature or the like as in the related art. Therefore, according to this embodiment, it is possible to achieve fabrication of a stable polarizing film having both high degree of polarization and high transmittance, namely, excellent optical properties.

Here, the acid catalyst may be a low volatility acid catalyst. According to this embodiment, the acid catalyst has low volatility and thus is unlikely to evaporate in the preparation of polyene. Thus, the method according to this embodiment may provide a more uniform acid concentration in the polyvinyl alcohol film in preparation of polyene.

In addition, the acid catalyst may have a weight loss rate of less than about 3 wt % at 100° C. According to this embodiment, since the acid catalyst has a weight loss rate of less than about 3 wt % at 100° C., the acid catalyst is unlikely to evaporate in preparation of polyene. Thus, the method according to this embodiment may provide a more uniform acid concentration in the polyvinyl alcohol in preparation of polyene.

Further, the acid catalyst may be an organic acid. According to this embodiment, since the acid catalyst is an organic acid, the acid catalyst is unlikely to evaporate in preparation of polyene. Thus, the method according to this embodiment may provide a more uniform acid concentration in the polyvinyl alcohol in preparation of polyene.

Further, the organic acid may have a functional group selected from the group consisting of a carboxylic acid group and a sulfonic acid group. According to this embodiment, since the organic acid has a functional group selected from the group consisting of a carboxylic acid group and a sulfonic acid group, the acid catalyst is unlikely to evaporate in preparation of polyene. Thus, the method according to this embodiment may provide a more uniform acid concentration in the polyvinyl alcohol in preparation of polyene.

Further, the coating liquid may include the acid catalyst in an amount of about 2 wt % to about 10 wt % based on the weight of the polyvinyl alcohol. According to this embodiment, the coating liquid includes the acid catalyst in an amount of about 2 wt % to about 10 wt % based on the weight of the polyvinyl alcohol. Accordingly, the method according to this embodiment may fabricate a polyene containing polarizing film having high degree of polarization as well as high transmittance.

Further, the coating liquid may include the acid catalyst in an amount of about 4.0 wt % to about 10.0 wt % based on the weight of the polyvinyl alcohol. According to this embodiment, the coating liquid includes the acid catalyst in an amount of about 4.0 wt % to about 10.0 wt % based on the weight of the polyvinyl alcohol. Accordingly, the method according to this embodiment may fabricate a polyene containing polarizing film having high degree of polarization as well as high transmittance.

Further, the content (or amount) of acid catalyst may be about 5 wt % based on the weight of the polyvinyl alcohol. According to this embodiment, since the content of the acid catalyst is about 5 wt % based on the weight of the polyvinyl alcohol, the method according to this embodiment may fabricate a polyene containing polarizing film having high degree of polarization as well as high transmittance.

According to another embodiment of the present invention, a polyene containing polarizing film may be fabricated by the method according to embodiments of the present invention. Since the polyene containing polarizing film according to this embodiment of the invention has both high degree of polarization and high transmittance, the polyene containing polarizing film is suitable for, for example, organic light emitting displays.

Here, the polyene containing polarizing film may have a thickness of less than about 10 μm. According to this embodiment, since the polyene containing polarizing film has a thickness of less than about 10 μm, shrinkage of the polyene containing polarizing film may be reduced even when the polyene containing polarizing film is applied to a large organic light emitting display. As a result, according to this embodiment, warpage or curling of the organic light emitting display may be reduced.

According to a further embodiment of the present invention, a polarizing plate may include the polyene containing polarizing film manufactured according to embodiments of the present invention. According to this embodiment of the present invention, since the polarizing plate has both high degree of polarization and high transmittance, the polarizing plate is suitable for, for example, organic light emitting displays.

According to yet another embodiment of the present invention, a display may include the polarizing plate manufactured according to embodiments of the present invention. According to this embodiment of the present invention, since the display includes the polarizing plate having both high degree of polarization and high transmittance, the display has excellent optical properties.

### BRIEF DESCRIPTION OF THE DRAWINGS

FIG. 1(a) is a sectional view of a polarizing film in the related art; and

FIG. 1(b) is a sectional view of a polarizing film according to one embodiment of the present invention.

### DETAILED DESCRIPTION

Embodiments will now be described in more detail with reference to the accompanying drawing. In the specification and drawings, components having substantially the same functions will be represented by the same reference numerals, and repeated descriptions thereof will be omitted.

Method of Fabricating a Polarizing Film

First, a method of fabricating a polarizing film according to one embodiment of the present invention will be described. The polyene containing polarizing film according to one embodiment of the invention is fabricated from a polyvinyl alcohol film including an acid catalyst. The method according to one embodiment of the present invention includes fabricating a polyvinyl alcohol film using a coating liquid including an acid catalyst and polyvinyl alcohol, and dehydrating the polyvinyl alcohol film.

Fabrication of a Polyvinyl Alcohol Film

In fabricating a polyvinyl alcohol film, a coating liquid including an acid catalyst and polyvinyl alcohol is prepared. Here, polyvinyl alcohol is introduced into water, followed by stirring and heating the mixture of water and polyvinyl alcohol, thereby sufficiently dissolving polyvinyl alcohol in water. Subsequently, an acid catalyst and a leveling agent are introduced into the aqueous solution of polyvinyl alcohol, followed by stirring to prepare a coating liquid.

Polyvinyl alcohol may have a degree of polymerization from about 1500 to about 5000, for example, from about 1500 to about 2500. For example, polyvinyl alcohol may have a degree of polymerization of about 1500, 1600, 1700, 1800, 1900, 2000, 2100, 2200, 2300, 2400 or 2500. Within this range, it is possible to reduce or prevent breakage of the polyvinyl alcohol film even upon wet stretching.

Polyvinyl alcohol may have a degree of saponification from about 95 mol % to about 100 mol %, for example, about 99.9 mol %. Within this range, the polyvinyl alcohol film may exhibit excellent durability and high stretchability.

In this embodiment, the acid catalyst may be pre-mixed with the coating liquid. As a result, polyvinyl alcohol may have a uniform acid concentration. Namely, the acid catalyst may be more uniformly dispersed in polyvinyl alcohol.

The acid catalyst may be a low volatility acid catalyst, without being limited thereto. When the acid catalyst has low volatility, evaporation of the acid catalyst may be reduced or prevented in preparation of polyene, thereby providing a more stable (and uniform) acid concentration in polyvinyl alcohol.

In one embodiment, the acid catalyst may have a weight loss of less than about 3 wt % at 100° C. When the weight loss rate of the acid catalyst at 100° C. is less than about 3 wt %, for example, from about 0.1 wt % to about 2.5 wt %, the acid concentration in polyvinyl alcohol may become more stable and more uniform in preparation of polyene. For example, the weight loss rate of the acid catalyst at 100° C. may be about 0.1 wt %, 0.2 wt %, 0.3 wt %, 0.4 wt %, 0.5 wt %, 0.6 wt %, 0.7 wt %, 0.8 wt %, 0.9 wt %, 1.0 wt %, 1.1 wt %, 1.2 wt %, 1.3 wt %, 1.4 wt %, 1.5 wt %, 1.6 wt %, 1.7 wt %, 1.8 wt %, 1.9 wt %, 2.0 wt %, 2.1 wt %, 2.2 wt %, 2.3 wt %, 2.4 wt %, 2.5 wt %, 2.6 wt %, 2.7 wt %, 2.8 wt %, or 2.9 wt %. The weight loss rate refers to a percentage obtained by measuring the initial weight of the acid catalyst and the weight of the acid catalyst after heating at 100° C. for 10 minutes, and dividing an absolute difference therebetween by the initial weight.

For example, the acid catalyst satisfying the aforementioned requirements may be an organic acid. The organic acid may have a functional group selected from the group consisting of carboxylic acid group and a sulfonic acid group, but is not limited thereto. The organic acid may be represented by R—X. Here, R may be any compound formed of carbon, hydrogen and fluorine, without limitation. For example, R may be a functional group selected from the group consisting of a C₁ to C₁₂ alkyl group, a C₁ to C₁₂ perfluoroalkyl group, a C₆ to C₁₂ aromatic functional group, and a C₆ to C₁₂ fluorine substituted aromatic functional group. X is a functional group selected from the group consisting of a carboxylic acid group and a sulfonic acid group. For example, the organic acid may be paratoluene sulfonic acid.

For example, the weight loss rate of paratoluene sulfonic acid upon heating at 100° C. for 10 minutes is below a detection limit (10 ppm or less) of an analytical instrument. The analytical instrument may include ion chromatography, or the like. The analysis includes heating a sample on a hot plate to collect the resulting gases. Subsequently, the gases are subjected to bubbling in water to substitute the gases. Then, quantitative analysis is performed through ion chromatography.

Further, since the concentration of a saturated aqueous solution of paratoluene sulfonic acid is higher than that of hydrochloric acid, an acid catalyst having a higher concentration may be dispersed in polyvinyl alcohol if paratoluene sulfonic acid is used as the acid catalyst. In addition, although the acid catalyst remaining in the polyene containing polarizing film may reduce durability of the polyene containing polarizing film, the paratoluene sulfonic acid may be more easily removed from the polyene containing polarizing film than hydrochloric acid.

Although the content ratio of the acid catalyst is not particularly limited, the acid catalyst may present in an amount of 2 wt % to 10 wt %, for example, 4.0 wt % to 10.0 wt %, based on the weight of polyvinyl alcohol. Within this range, reaction time may be reduced while inhibiting side reaction. For example, the acid catalyst may present in an amount of about 2 wt %, 2.5 wt %, 3.0 wt %, 3.5 wt %, 4.0 wt %, 4.5 wt %, 5.0 wt %, 5.5 wt %, 6.0 wt %, 6.5 wt %, 7.0 wt %, 7.5 wt %, 8.0 wt %, 8.5 wt %, 9.0 wt %, 9.5 wt %, or 10 wt % based on the weight of polyvinyl alcohol.

Further, dehydration may be easily controlled while preventing corrosion of the fabrication apparatus. For example, when the content of the acid catalyst is less than 4 wt % based on the weight of polyvinyl alcohol, it takes more than 10 minutes to initiate dehydration reaction at a dehydration temperature of 140° C. and it takes a long time to complete the dehydration reaction (provided that the dehydration reaction proceeds).

In one embodiment, the acid catalyst may present in an amount of about 5 wt % based on the weight of polyvinyl alcohol. In this content of the acid catalyst, a polyene containing polarizing film having both high transmittance and high degree of polarization may be fabricated. The degree of polarization of the polyene containing polarizing film may be controlled by the content of the acid catalyst. A higher amount of the acid catalyst provides a higher amount of polyene (namely, carbon-carbon double bonds) in polyvinyl alcohol, thereby increasing the degree of polarization.

Transmittance tends to increase as the distribution of components contributing to polarization (such as the carbon-carbon double bonds in a polyene containing polarizing film, iodine in an iodine based polarizing film, or the like) becomes uniform. Since a typical method of fabricating a polyene containing polarizing film fails to achieve a uniform acid concentration in polyvinyl alcohol, the polyene containing polarizing film has a non-uniform distribution of carbon-carbon double bonds. For this reason, the polarizing film has a non-uniform degree of polarization and non-uniform transmittance. Conversely, according to the embodiment of the present invention, since the acid catalyst is previously added to polyvinyl alcohol (i.e., the acid catalyst is added to polyvinyl alcohol to make a coating liquid before forming the polyvinyl alcohol film), a desired concentration of the acid catalyst may be more uniformly dispersed in polyvinyl alcohol. Therefore, in the method according to the embodiment of the present invention, it is possible to fabricate a polyene containing polarizing film having both high transmittance and high degree of polarization.

The leveling agent may be a perfluoroalkylethylene oxide adduct, without being limited thereto.

Next, the coating liquid is coated onto a substrate (for example, a non-stretched film), followed by drying the coating liquid to form a polyvinyl alcohol film on the substrate. Although the thickness of the polyvinyl alcohol film is not particularly limited, the thickness of the polyvinyl alcohol film may be adjusted to about 10 μm or less. In one embodiment, the polyvinyl alcohol film including the acid catalyst may have a thickness of about 0.5 μm to about 10.0 μm. Within this range, the polyvinyl alcohol film may be used for polarizing plates, and may be reduced or prevented from breaking upon elongation.

Dehydration of Polyvinyl Alcohol

In dehydrating polyvinyl alcohol, polyvinyl alcohol in the polyvinyl alcohol film is subjected to dehydration to form polyene (carbon-carbon double bonds). Here, the polyvinyl alcohol film is heated to perform dehydration of polyvinyl alcohol. In this embodiment, since the acid catalyst is uniformly dispersed in polyvinyl alcohol film, carbon-carbon double bonds are uniformly generated in polyvinyl alcohol film. Temperature and time for heating are not particularly limited and may be suitably adjusted according to a desired degree of polarization.

While performing dehydration of polyvinyl alcohol, the polyvinyl alcohol film may be stretched in a set or predetermined direction. Hereinafter, stretching performed in a liquid will be referred to as “wet stretching”, while stretching performed in a gas (for example, in an atmosphere) will be referred to as “dry stretching”. By such stretching operation, orientations of the carbon-carbon double bonds may be coincided with each other. Further, the polyvinyl alcohol film may be stretched in a ratio from about 1.1 to about 6 times an initial length thereof, for example, about 4 times, or for example, about 1.5, 2.0, 2.5, 3.0, 3.5, 4.0, 4.5, 5.0, 5.5, or 6 times, without being limited thereto. Dry stretching and wet stretching described below may be performed after aligning the film with the substrate.

Dehydration and dry stretching may include treating the polyvinyl alcohol film at about 50° C. to about 150° C. for about 1 minute to 20 minutes.

Next, the polyvinyl alcohol film is dipped in an aqueous solution of boric acid, followed by stretching the film in the aqueous solution of boric acid in the same direction as in dry stretching. Namely, polyvinyl alcohol is wet stretched. Wet stretching may be performed to have a stretch ratio ranging from about 1.1 times to 3.5 times, for example about 1.5 times of the length before conducting the wet stretching, without being limited thereto. When the stretch ratio of dry stretching is 4 times and the stretch ratio of wet stretching is 1.5 times, the polyvinyl alcohol film is stretched in a total of 6 times the initial length thereof. Subsequently, the polyvinyl alcohol film is dried to form a polyene containing polarizing film. The aqueous solution of boric acid may be an aqueous solution containing about 0.1 wt % to about 5 wt % of boric acid. Within this range, the polyene may have the effect of securing the double bonds.

Wet stretching may include the act of stretching the polyvinyl alcohol film in an aqueous solution of boric acid at about 20° C. to about 60° C. (for example, at about 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, or 60° C.) for about 1 minute to about 20 minutes.

As such, according to this embodiment, since the acid catalyst is added to the coating liquid, it is possible to uniformly disperse the acid catalyst of high concentration in the polyvinyl alcohol film. Accordingly, according to this embodiment, it is possible to fabricate a polyene containing polarizing film in which multiple carbon-carbon double bonds are uniformly dispersed. Namely, in this embodiment, it is possible to fabricate a polyene containing polarizing film having both high degree of polarization and high transmittance. Further, in this embodiment, non-uniformity of the polyene containing polarizing film may be decreased. Further, since impregnation of polyvinyl alcohol in an aqueous solution of the acid catalyst becomes unnecessary, the fabrication process may be simplified.

In this embodiment, since the acid catalyst is added to the coating liquid, the acid catalyst of high concentration may be uniformly dispersed in the polyvinyl alcohol film even if a polyvinyl alcohol film is formed to a low thickness. Accordingly, in this embodiment, the polyene containing polarizing film having a low thickness, a high degree of polarization, and high transmittance may be fabricated. For example, in this embodiment, the polyene containing polarizing film may have a thickness of less than about 10 μm, for example, from about 1 μm to about 5 μm, a transmittance of about 44% or more, for example, from about 44% to about 46%, and a degree of polarization of about 97% or more, for example, from 98% to 100%. When the organic acid is used as the acid catalyst, evaporation of the acid catalyst in preparation of polyene may be reduced or inhibited, thereby enhancing the degree of polarization.

On the other hand, in a comparable method in the related art, the polyvinyl alcohol film is impregnated in the aqueous solution of an acid catalyst such as hydrochloric acid. However, when the polyvinyl alcohol film has a thin thickness, it is difficult to impregnate the polyvinyl alcohol film with a sufficient amount of the acid catalyst. Further, since hydrochloric acid is likely to volatilize, hydrochloric acid may be evaporated in preparation of polyene. For this reason, in the comparable method, polyene, that is, the carbon-carbon double bonds are insufficiently produced, thereby making it difficult to fabricate a polyene containing polarizing film which has a thin thickness and exhibits a high degree of polarization.

The acid catalyst may be removed by dipping the polyene containing polarizing film in water or in an aqueous inorganic solution, such as a weak alkali water solution, a saline solution, or the like.

The acid catalyst may present in an amount of about 0.001 wt % or less in the polyene containing polarizing film. Within this range, the acid catalyst may not influence the properties of the polarizing film, such as the degree of polarization, transmittance, or the like.

The polyene containing polarizing film is then separated from the substrate and is combined with a protective film and a retardation film (λ/4 film), and the like to fabricate a polarizing plate.

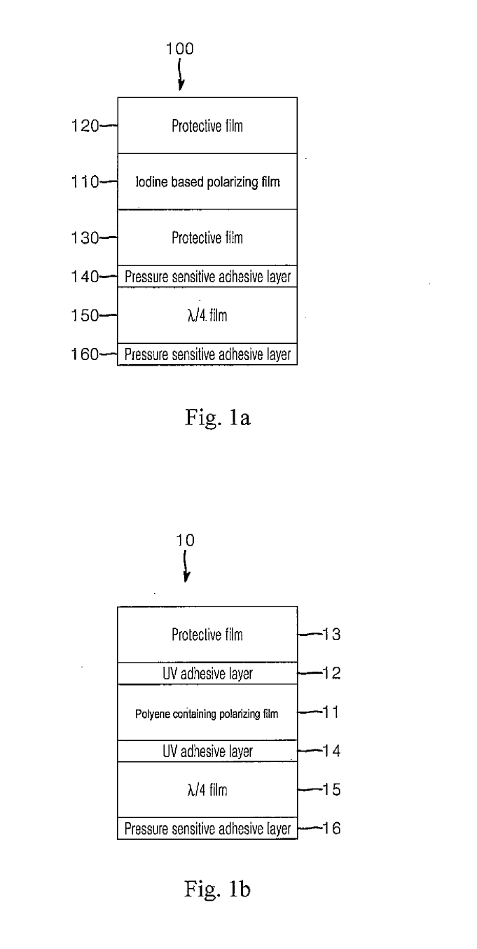

One example of the polarizing plate is shown in FIGS. 1(a) and 1(b). FIG. 1(b) shows a polarizing plate 10 according to one embodiment of the invention compared with a typical iodine based polarizing plate 100 shown in FIG. 1(a). Here, FIG. 1(a) shows a typical iodine based polarizing plate 100 and FIG. 1(b) shows a polarizing plate 10 according to one embodiment of the invention.

A typical polarizing plate 100 includes an iodine based polarizing film 110, protective films 120 and 130, pressure sensitive adhesive layers 140 and 160, and a retardation film (λ/4 film) 150. The iodine based polarizing film 110 has a high thickness to achieve a desired degree of polarization. For example, the iodine based polarizing film 110 may have a thickness of 22 μm or more. As a result, the overall thickness of the polarizing plate 100 increases. For example, the polarizing plate 100 may have a thickness of 190 μm or more.

The polarizing plate 10 according to one embodiment may include a polyene containing polarizing film 11, UV adhesive layers 12 and 14, a protective film 13, a retardation film (λ/4 film) 15, and a pressure sensitive adhesive layer 16.

Accordingly, the polarizing plate 10 is made of a circularly polarizing film. Further, the polarizing plate 10 according to this embodiment may be made of suitable known materials in addition to the polyene containing polarizing film 11. The pressure sensitive adhesive layer 16 is adhered to, for example, a display side of a display device. In this embodiment, since the polyene containing polarizing plate 11 has a low thickness, the overall polarizing plate 10 including the polyene containing polarizing film also has a low thickness. In this embodiment, the polarizing plate 10 may have a thickness of 100 μm or less. It should be understood that the polarizing plate according to the present invention may have different structures. The polarizing plate may not be a circularly polarizing film. The polarizing plate may have a transmittance of about 44% or more, for example, from about 44% to about 46%, and a degree of polarization of about 97% or more, for example, from about 98% to about 100%.

### EXAMPLE

### Example 1

One embodiment of the present invention is described in Example 1. In Example 1, a polyene containing polarizing film and a polarizing plate were fabricated as follows.

Fabrication of a Polyvinyl Alcohol Film

First, polyvinyl alcohol (JC-25, Japan VAM & POVAL Co., Ltd.) was introduced into water as a solvent. The mixture of water and polyvinyl alcohol was heated while being stirred, thereby sufficiently dissolving polyvinyl alcohol in water. Paratoluene sulfonic acid and a leveling agent (Megapak, DIC Corporation) were added to the aqueous solution of polyvinyl alcohol, followed by stirring to prepare a coating liquid. The impregnation ratio (weight ratio) of water, polyvinyl alcohol and paratoluene sulfonic acid in the coating liquid was 89.5 wt %:10 wt %:0.5 wt %. Further, the content of the leveling agent was a minor amount. That is, the leveling agent was present in an amount of 0.002 wt % based on the total weight of water, polyvinyl alcohol and paratoluene sulfonic acid.

Next, a non-stretched film formed of isophthalic acid copolymeric polyethylene terephthalate (PET) was prepared as a substrate, followed by coating the coating liquid onto the substrate. Subsequently, the coating liquid was dried to fabricate a polyvinyl alcohol film. The polyvinyl alcohol film had a thickness of 10 μm.

Dehydration of Polyvinyl Alcohol

The polyvinyl alcohol film was placed in an oven preheated to 140° C., followed by heating at 140° C. for 120 seconds, thereby dehydrating polyvinyl alcohol from the polyvinyl alcohol film to prepare polyene (carbon-carbon double bonds). While performing dehydration of the polyvinyl alcohol, the polyvinyl alcohol film and the substrate were aligned and dry stretched to 4 times the initial length thereof in a set or predetermined direction.

Next, the polyvinyl alcohol film was dipped into an aqueous solution of 5 wt % boric acid (containing 5 wt % boric acid based on the total weight of the aqueous solution) preheated to 85° C. The polyvinyl alcohol film and the substrate were subjected to wet stretching to 1.5 times the initial length thereof (i.e., the length of the polyvinyl alcohol film prior to the wet stretching) in the aqueous solution of boric acid in the same direction as the dry stretching. As a result, the polyvinyl alcohol film was stretched to a total length of 6 times the initial length thereof. Thereafter, the polyvinyl alcohol film was placed in an oven preheated to 80° C., followed by drying at 80° C. for 2 minutes, thereby fabricating a polyene containing polarizing film prepared in Example 1. The polyene containing polarizing film had a thickness of 5 μm.

Subsequently, a UV adhesive was prepared using the following components.

90 wt % of (a), 10 wt % of (b), 1 wt % of (c) and 2 wt % of (d) were mixed using a stirrer. The content ratio of (c) and (d) was respectively calculated based on the total weight of (a)+(b).

(a) 4HBA (4-hydroxybutyl acrylate)

(b) Celloxide 2021P (3,4-epoxycyclohexylmethyl 3,4-epoxycyclohexane carboxylate) (Daicel Corporation)

(c) TPO (2,4,6-trimethylbenzoyl-diphenyl-phospine oxide) (Ciba Specialty Chemicals Holding Inc.)

(d) CPI-110P ((p-phenylthiophenyl)diphenyl sulfonium PF₆⁻ salt) (SAN-APRO LTD.)

The UV adhesive was applied to a thickness of 2 μm on a surface of the polyene containing polarizing film (a surface opposite to the one contacting the substrate). Subsequently, a 50 μm thick protective film (UV absorber-containing triacetyl cellulose-based film, FUJITAK, FUJI FILM Corporation) was laminated on the surface of the polyene containing polarizing film via the UV adhesive applied to the surface of the film. As a result, the laminated layer including the polyene containing polarizing film and the substrate was adhered to the protective film. Next, the laminated layer was irradiated with UV light at 1000 mJ to cure the UV adhesive. Subsequently, the substrate was separated from the polyene containing polarizing film.

Next, the UV adhesive was applied to a thickness of 2 μm on the backside of the polyene containing polarizing film (a surface of the polyene containing polarizing film exposed by separation from the substrate). A 50 μm thick retardation film (λ/4 plate, WRS, Teijin Chemicals Ltd.) was attached to the backside of the polyene containing polarizing film such that an angle defined between an optical absorption axis of the polyene containing polarizing film and a slow axis of the A/4 plate was 45°, followed by curing the UV adhesive in the same manner as above to fabricate a polarizing plate for evaluation.

### Comparative Example

A polyene containing polarizing film and a polarizing plate according to Comparative Example were fabricated by the following treatment.

First, polyvinyl alcohol (JC-25, Japan VAM & POVAL Co., Ltd.) was introduced into water as a solvent. The mixture of water and polyvinyl alcohol was heated while being stirred, thereby sufficiently dissolving polyvinyl alcohol in water. Leveling agent (Megapak, DIC Corporation) was added to the aqueous solution of polyvinyl alcohol, followed by stirring to fabricate a coating liquid. The ratio (weight ratio) of water, polyvinyl alcohol and leveling agent in the coating liquid was 90 wt %:10 wt %:0.002 wt %. Here, the content of the leveling agent was 0.002 wt % based on the total weight of water and polyvinyl alcohol.

Next, a non-stretched film formed of isophthalic acid copolymeric polyethylene terephthalate (PET) was prepared as a substrate, followed by coating the coating liquid onto the substrate. Subsequently, the coating liquid was dried to fabricate a polyvinyl alcohol film. The polyvinyl alcohol film had a thickness of 10 μm.

Next, the polyvinyl alcohol film was dipped in an aqueous solution of 0.5 wt % hydrochloric acid (containing 0.5 wt % hydrochloric acid based on the total weight of the aqueous hydrochloric acid solution) adjusted to 10° C., followed by wet stretching of the polyvinyl alcohol film to 3 times an initial length thereof in a set or predetermined direction. Namely, in Comparative Example, the polyvinyl alcohol film was impregnated in an aqueous hydrochloric acid solution, and then subjected to wet stretching.

The polyvinyl alcohol film was removed from the aqueous hydrochloric acid solution, followed by placing the film in an oven preheated to 65° C. Thereafter, the polyvinyl alcohol film was dried at 65° C. for 15 minutes. The resulting polyvinyl alcohol film was placed in an oven preheated to 130° C., followed by dry stretching the film to 2 times the initial length thereof in the same direction as in wet stretching. Namely, the polyvinyl alcohol film was stretched to a total length of 6 times the initial length thereof. Subsequently, the polyvinyl alcohol film was heated to 130° C. for 30 minutes, followed by dehydrating the polyvinyl alcohol film to fabricate a polyene containing polarizing film. Then, a polarizing plate was fabricated through the same procedure as in Example 1.

Property Evaluation

The degree of polarization and transmittance (simple substance transmittance) of the polarizing plates according to Example 1 and Comparative Example were evaluated in accordance with the following treatment.

Measurement instrument: UV-Vis spectrophotometer (V7100, fabricated by JASCO Corporation)

Measurement method: Transmittance (T), parallel transmittance (Tp), and crossed transmittance (perpendicular transmittance) (Tc) of the polarizing device were measured. These represent Y values obtained by measuring 2 degree viewing angle (C light source) in accordance with JIS Z8701, followed by color correction. The degree of polarization was calculated from Equation 1 using these transmittance values.

Degree of polarization(P)(%)={(Tp−Tc)/(Tp+Tc)}^{1/2}×100 Equation 1

Measurement results are shown in Table 1.

TABLE 1

| | T | P |
|---|---|---|
| Example 1 | 44.90% | 97.085% |
| Comparative Example | 44.03% | 96.506% |

According to this evaluation, it may be observed that the polarizing plate according to Example 1 exhibits both high degree of polarization and high transmittance. On the contrary, the polarizing plate according to Comparative Example exhibits both low degree of polarization and transmittance. Since the coating liquid includes an organic acid as an acid catalyst in Example 1, a high concentration of the acid catalyst is uniformly dispersed in the polyvinyl alcohol film. Further, since the organic acid has low volatility, the acid catalyst is unlikely to volatilize in preparation of polyene. Accordingly, in Example 1, multiple carbon-carbon double bonds are uniformly formed, thereby providing a high degree of polarization and high transmittance. On the other hand, in Comparative Example, since the polyvinyl alcohol film is impregnated with an aqueous hydrochloric acid solution, hydrochloric acid is non-uniformly dispersed in polyvinyl alcohol film. In addition, since hydrochloric acid tends to volatize, the acid catalyst is vaporized in preparation of polyene. Thus, not only is the number of carbon-carbon double bonds less than that of Example 1, but also the distribution of the double bonds is non-uniform.

### Examples 2 to 4

In Examples 2 to 4, content ratio of paratoluene sulfonic acid to polyvinyl alcohol was varied. In Examples 2 to 4, a series of procedures was performed in the same manner as in Example 1 except that the content ratio of paratoluene sulfonic acid and dehydration time (heating time) upon dry stretching were changed as listed in Table 2, thereby fabricating dry-stretched films according to Examples 2 to 4. Each of these dry stretched films included a polyvinyl alcohol film and a substrate.

Further, transmittance (single transmittance) of the dry-stretched films prepared in Examples 2 to 4 was measured in the same manner as in Example 1. Measurement results are shown in Table 2. Further, the transmittance of the dry-stretched film prepared in Example 1 is also listed in Table 2.

TABLE 2

| | Content of acid | Dehydration | |
|---|---|---|---|
| | catalyst | Time | Transmittance |
| Example 1 | 5 wt % | 2 min. | 40.3% |
| Example 2 | 10 wt % | 1 min. | 27% |
| Example 3 | 4 wt % | 10 min. | 39% |
| Example 4 | 2 wt % | 45 min. | 40% |

Although the transmittance of the polarizing films prepared in Examples 1, 3 and 4 was less than 44%, the transmittance could be increased to 44% or more by subjecting the dry stretched film to wet stretching as in Example 1. In addition, although the transmittance of the polarizing film prepared in Example 2 was lower than that of the polarizing films prepared in Examples 1, 3 and 4, the transmittance of the polarizing film of Example 2 could be increased to about 40% by changing the dehydration time to less than 1 minute. Namely, since dehydration proceeded rapidly when the content ratio of the acid catalyst was high, reaction proceeded excessively only for a dehydration time of 1 minute. Thus, in Example 2, the transmittance of the polarizing film could be enhanced to about 40% by reducing the dehydration time. Further, in Example 4, although the transmittance of the polarizing time was high, dehydration was performed for too long a time. When polarizing films are produced in a roll-to-roll manner, drying time increases with increasing dehydration time. As such, the content of the acid catalyst may be from 4 wt % to 10 wt % in terms of having good transmittance and dehydration time.

The method of fabricating a polyene containing polarizing film according to this embodiment includes fabricating a polyvinyl alcohol film using a coating liquid including an acid catalyst and a polyvinyl alcohol, and dehydrating the polyvinyl alcohol film.

The method allows a high concentration of the acid catalyst to be uniformly dispersed in the polyvinyl alcohol film, thereby enabling fabrication of a polyene containing polarizing film in which multiple carbon-carbon double bonds are uniformly formed without the need of accurate control of temperature and the like as in the related art. Therefore, the method according to the embodiment of the invention is capable of stably fabricating a polyene containing polarizing film having both high degree of polarization and high transmittance, i.e., a polarizing film having excellent optical properties.

In addition, the polyene containing polarizing film having high degree of polarization and high transmittance is suitable for anti-reflective polarizing plates for organic light emitting displays, which are expected to have widespread use in the near future. Since the polyene containing polarizing film has (e.g., essentially has) strong durability with respect to high temperature and high humidity, the polyene containing polarizing film according to the embodiment of the invention exhibits not only excellent optical properties but also high durability with respect to high temperature and high humidity. A display device including such a polyene containing polarizing film may have improved optical properties.

Further, since the acid catalyst is low volatile, the acid catalyst is unlikely to evaporate in preparation of polyene. Accordingly, the method according to the embodiment of the invention may provide a more uniform acid concentration in polyvinyl alcohol even during preparation of polyene.

Further, since the acid catalyst has a weight loss rate of less than 3 wt % at 100° C., the acid catalyst is unlikely to evaporate in preparation of polyene. Accordingly, the method according to the embodiment of the invention may provide a more uniform acid concentration in polyvinyl alcohol in preparation of polyene.

Further, since the acid catalyst is an organic acid, the acid catalyst is unlikely to evaporate in preparation of polyene. Accordingly, the method according to the embodiment of the invention may provide a more uniform acid concentration in polyvinyl alcohol in preparation of polyene.

Further, since the organic acid has a functional group selected from the group consisting of a carboxylic acid group and a sulfonic acid group, the organic acid is unlikely to evaporate in preparation of polyene. Accordingly, the method according to the embodiment of the invention may provide a more uniform acid concentration in polyvinyl alcohol in preparation of polyene.

Furthermore, in the method according to the embodiment of the invention, the coating liquid includes the acid catalyst in an amount of 2 wt % to 10 wt %, for example, in an amount of 4.0 wt % to 10.0 wt %, based on the weight of the polyvinyl alcohol. Therefore, the method according to the embodiment of the invention may provide a polyene containing polarizing film having both high degree of polarization and high transmittance.

The content of the acid catalyst may be 5 wt % based on the weight of polyvinyl alcohol, and hence the method according to the embodiment of the invention may provide a polyene containing polarizing film having both a high degree of polarization and high transmittance.

Furthermore, the method according to the embodiment of the invention may reduce the thickness of the polyene containing polarizing film. For example, the method according to the embodiment of the invention may reduce the thickness of the polyene containing polarizing film to less than 10 μm. As a result, shrinkage of the polyene containing polarizing film and bending of a large organic light emitting display may be suppressed even when the polyene containing polarizing film is applied to a large organic light emitting display.

Although some embodiments have been provided with reference to the accompanying drawings, it should be understood that these embodiments are given by way of illustration only, and that various modifications, variations, and alterations may be made without departing from the spirit and scope of the present invention. The scope of the present invention should be limited only by the accompanying claims and equivalents thereof.

What is claimed is:

1. A method of fabricating a polyene containing polarizing film, comprising:
fabricating a polyvinyl alcohol film using a coating liquid comprising an acid catalyst and a polyvinyl alcohol; and
dehydrating the polyvinyl alcohol film.

2. The method according to claim 1, wherein the acid catalyst is an acid with low volatility.

3. The method according to claim 2, wherein the acid catalyst has a weight loss rate of less than about 3 wt % at 100° C.

4. The method according to claim 2, wherein the acid catalyst comprises an organic acid.

5. The method according to claim 4, wherein the organic acid comprises a functional group selected from the group consisting of a carboxylic acid group and a sulfonic acid group.

6. The method according to claim 1, wherein the coating liquid comprises the acid catalyst in an amount of about 2 wt % to about 10 wt % based on a weight of the polyvinyl alcohol.

7. The method according to claim 6, wherein the coating liquid comprises the acid catalyst in an amount of about 4.0 wt % to about 10.0 wt % based on the weight of the polyvinyl alcohol.

8. The method according to claim 7, wherein the coating liquid comprises the acid catalyst in an amount of 5 wt % based on the weight of the polyvinyl alcohol.

9. The method according to claim 1, wherein the polyvinyl alcohol has a degree of polymerization from about 1500 to about 5000.

10. The method according to claim 1, further comprising:
wet stretching the polyvinyl alcohol film after dehydration.

11. The method according to claim 10, wherein the wet stretching comprises stretching the polyvinyl alcohol film in an aqueous solution of boric acid at a temperature of about 20° C. to 60° C.

12. A polyene containing polarizing film fabricated by the method according to claim 1.

13. The polyene containing polarizing film according to claim 12, wherein the polyene containing polarizing film has a thickness of less than about 10 μm.

14. A polyene containing polarizing film fabricated from a polyvinyl alcohol film comprising an acid catalyst.

15. A polarizing plate comprising the polyene containing polarizing film according to claim 12.

16. The polarizing plate according to claim 15, wherein the polarizing plate has a transmittance of about 44% or more and a degree of polarization of about 97% or more.

17. A display comprising a polarizing plate according to claim 15.
